(19) United States
(12) Patent Application Publication
(10) Pub. No.: US 2014/0176170 A1
(43) Pub. Date: Jun. 26, 2014

(54) TEST TABLE WITH DRY ENVIRONMENT

(71) Applicant: CHROMA ATE INC., Tao-Yuan (TW)

(72) Inventors: Xin-Yi WU, Tao-Yuan Hsien (TW); Hsuan-Jen SHEN, Tao-Yuan (TW); Hung-Ta KAO, Tao-Yuan (TW)

(73) Assignee: CHROMA ATE INC., Tao-Yuan (TW)

(21) Appl. No.: 14/108,167

(22) Filed: Dec. 16, 2013

(30) Foreign Application Priority Data
Dec. 24, 2012 (TW) 101149519

(51) Int. Cl. G01R 31/26

(52) U.S. Cl. CPC G01R 31/2601
USPC 324/750.14

(57) ABSTRACT

A test table including a chuck base, a flow guide mechanism and a dry air generator is provided. The chuck base includes a test area. The flow guide mechanism is disposed around the chuck base. The dry air generator connects to the flow guide mechanism for generating a dry air. The flow guide mechanism guides the dry air to flow toward the test area to cover the test area and the object to be tested and to create a dry environment to prevent dew condensation.

This application claims the benefits of the Taiwan Patent Application Serial NO. 101149519 filed on Dec. 24, 2012, the subject matter of which is incorporated herein by reference.

### BACKGROUND OF THE INVENTION

1. Field of the Invention

The present invention relates to a test table with dry environment and more particularly, relates to a test table comprising a flow guide mechanism to guide a dry air to a test area so as to create a dry environment.

2. Description

As the science and technology is developing, people are caring more about environmental protection. Reducing carbon emission and saving energy are important issues and goals for countries in the world. As a result, incandescent lamps, fluorescent lamps, halogen lamps, high-pressure sodium lamps are being replaced by LEDs. LEDs have advantages of less fragile, energy-saving, environmentally friendly, non-mercury, directionality of light source, smaller, board color gamut, suitable for low-temperature environment, less light pollution and long working life; therefore, LEDs are widely utilized and revolutionizing traditional lights such as incandescent lamps and so on, becoming major light sources since LEDs keep to the point of energy-saving and environmentally friendliness.

Present manufacturing process of LEDs includes epitaxial silicon process of forming an epitaxial wafer on a substrate having base material, chip process of using wafers to produce multiple LED chips, packaging process of LED chips produced via the chip process, testing process of testing LED chips processed by the packaging process. In traditional testing process, the LED chips are performed with electrical property test on a test table so the optical property and current property of each LED chip on each wafer are understood; further, when performing electrical property test, testing environment usually needs to be in room temperature or in various temperatures such as low temperature of −40° C. or −50° C. or high temperature of 135° C. However, since the humidity of the testing environment of conventional test table is higher, when the test is performed in low temperature environment, dew condensation or even icing may occur on LED chips, which will affect the results of the electrical property test. Thus, techniques nowadays are to be improved.

### SUMMARY OF THE INVENTION

In prior art, when the test is performed in low temperature environment, dew condensation or even icing may occur on LED chips, which will affect the results of the electrical property test. Thus, the test table needs to be placed in a dry room completely isolated from the outside to avoid dew condensation. But if the LED chips need to be maintained during the test or after the test, its system needs to be restored to room temperature for further process, which is very inconvenient.

Thus, a test table with dry environment is provided according to embodiments of the present invention. The test table comprises a flow guide mechanism to guide a dry air to a test area so as to create a dry environment covering the test table and the objects to be tested to prevent dew condensation.

The test table comprises a chuck base, a flow guide mechanism and a dry air generator. The chuck base has a test area. The flow guide mechanism is disposed around the chuck base. The dry air generator connects to the flow guide mechanism for generating a dry air. The flow guide mechanism guides the dry air to flow toward the test area to cover the test area and the object to be tested and to create a dry environment to prevent dew condensation.

The flow guide mechanism comprises a guiding part. The guiding part guides the dry air to flow toward the test area when the dry air flows to the guiding part guiding part. The flow guide mechanism further comprises a plurality of outlets. The dry air flows from the outlets to the guiding part. The flow guide mechanism further comprises an inlet for connecting the dry air generator. The dry air enters the flow guide mechanism from the inlet and flowing to the outlets. The guiding part comprises a guiding angle for increasing a flow uniformity of the dry air flowing toward the test area.

The test table tests a wafer of LED chips. The test table further comprises a housing for and a dry air tub. The housing covers an upper space of the test area. The dry air pipe connects the dry air generator. The dry air generator is disposed inside the housing for to generate a dry environment in the upper space of the test area to prevent dew condensation. The dry air generator comprises an air filter. The chuck base has a function of temperature controlling to control the temperature of the test area.

Compared with prior art, the test table according to embodiments of the present invention comprises the flow guide mechanism to guide a dry air to the test area so as to create a dry environment covering the test table and the objects to be tested to prevent dew condensation or icing; therefore, the reliability of the electrical property test is improved.

### BRIEF DESCRIPTION OF THE DRAWINGS

Other features and advantages of this invention will become more apparent in the following detailed description of the preferred embodiments of this invention, with reference to the accompanying drawings.

FIG. 1 is a schematic view of a test table with dry environment according to the first embodiment of the present invention.

FIG. 2 is a cross-sectional and three-dimensional view of a chuck base and a flow guide mechanism according to the first embodiment of the present invention.

FIG. 3 is a cross-sectional and three-dimensional view of a chuck base and a flow guide mechanism of a test table according to the second embodiment of the present invention.

FIG. 4 is a cross-sectional view of a test table with dry environment according to the third embodiment of the present invention.

### DETAILED DESCRIPTION OF THE PREFERRED EMBODIMENT

The present invention relates to a test table. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

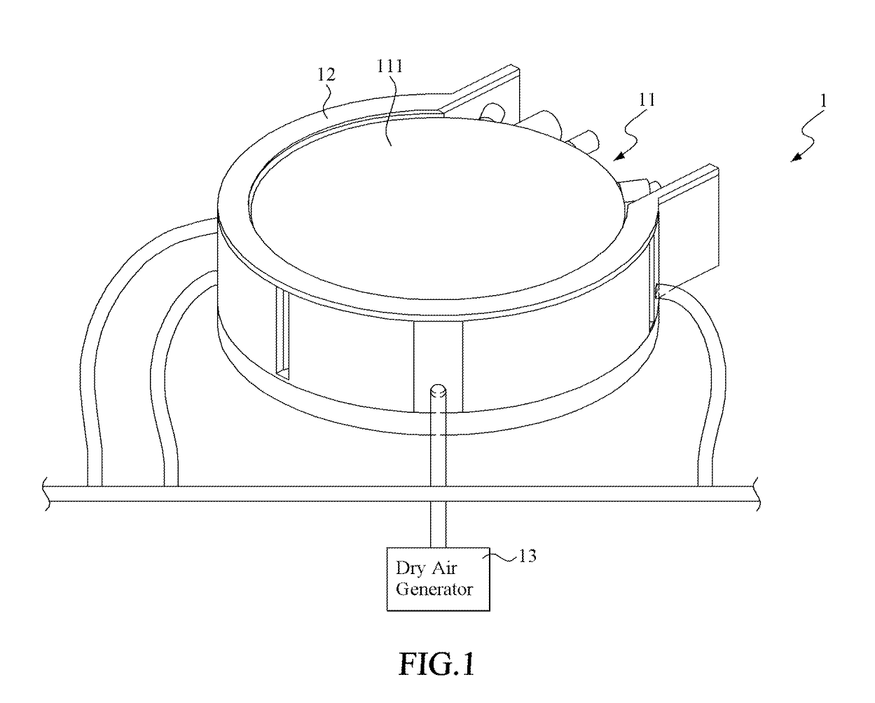

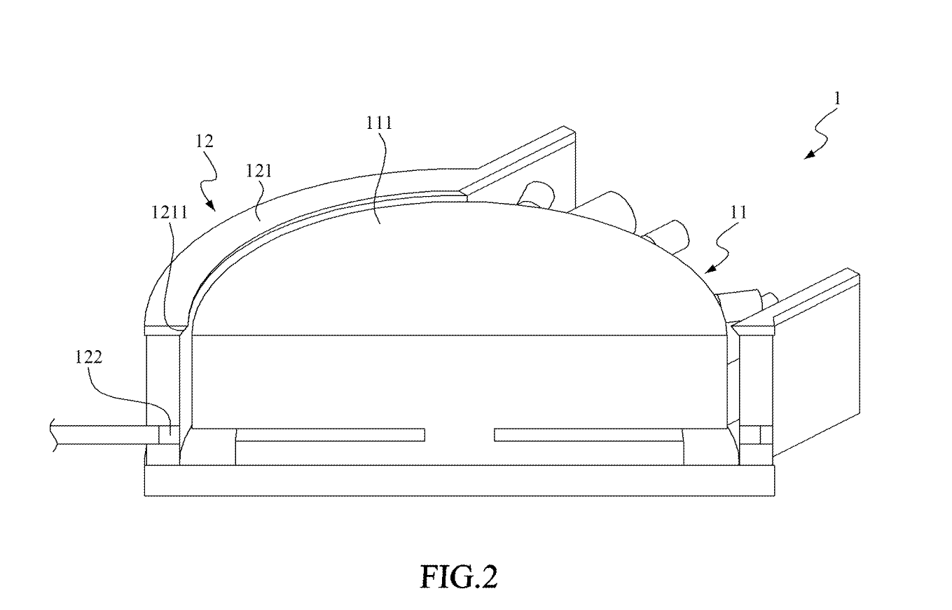

Refer to FIG. 1 and FIG. 2. FIG. 1 is a schematic view of a test table with dry environment according to the first embodiment of the present invention; FIG. 2 is a cross-sectional and three-dimensional view of a chuck base and a flow guide mechanism according to the first embodiment of the present invention. According to the first embodiment of the present invention, the test table 1 tests a wafer of LED chips. In other embodiments of the present invention, the objects to be tested are not limited to a wafer of LED chips. The test table 1 comprises a chuck base 11, a flow guide mechanism 12 and a dry air generator 13. The chuck base 11 has a test area 111 for storing the wafer to perform electrical property test and the chuck base 11 controls the temperature of the test area 111.

The flow guide mechanism 12 is disposed around the chuck base 11; further speaking, the flow guide mechanism 12 is disposed surrounding and near the chuck base 11. There is a gap between the flow guide mechanism 12 and the chuck base 11. The flow guide mechanism 12 comprises metal materials having rigidity. The flow guide mechanism 12 comprises a guiding part 121 and four inlets 122 (only one is numbered). The guiding part 121 comprises a guiding angle 1211 shielding the gap. The angle of the guiding angle 1211 is 30 degrees or 45 degrees (measured from the surface of the guiding part 1211).

The dry air generator 13 connects the flow guide mechanism 12; further speaking, the dry air generator 13 connects the inlet 122 via a pipe (not shown). The dry air generator 13 generates a dry air and comprises an air filter according to the first embodiment of the present invention.

When the user starts the test table 1 according to the first embodiment of the present invention, the dry air generator 13 generates a dry air flowing via the pipe, the gap and the inlets 122. After the dry air flows to the guiding part 121, it flows toward the test area 111 under the guidance of the flow guide mechanism 12 so as to form a dry environment for the test area 111 to prevent dew condensation, wherein the guiding angle 1211 increases the flow uniformity of the dry air flowing toward the test area 111.

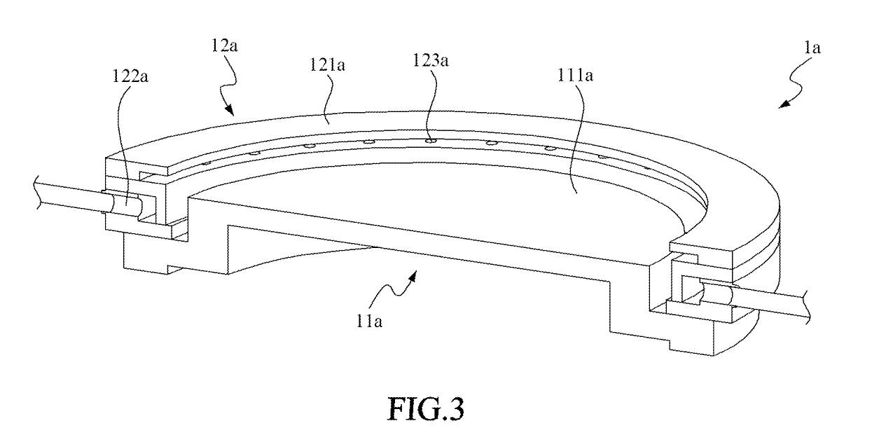

Refer to FIG. 3, a cross-sectional and three-dimensional view of a chuck base and a flow guide mechanism of a test table according to the second embodiment of the present invention. The difference between the first embodiment and the second embodiment is that according to the second embodiment of the present invention, the flow guide mechanism 12a only comprise a guiding part 121a, a plurality of inlets 122a (only one is numbered) and a plurality of outlets 123a (only one is numbered) and does not comprise the guiding angle 1211 of the first embodiment. When the user starts a test table 1a, the dry air enters the flow guide mechanism 12 via the inlets 122a and flows to the outlets 123a. The dry air then flows to the guiding part 121a from the outlets 123a and flows toward a test area 111a under the guidance of the guiding part 121a.

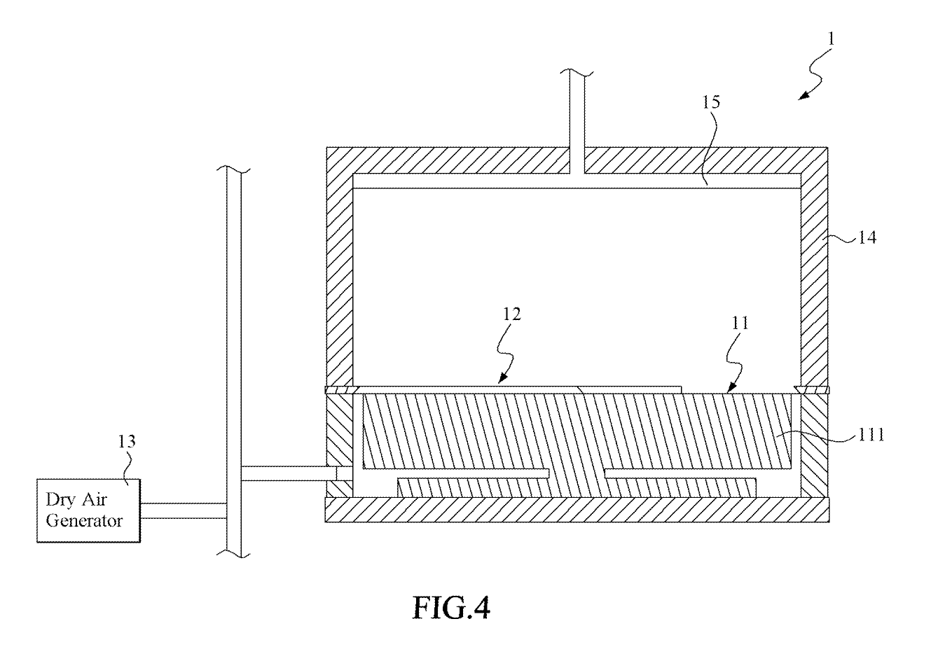

Refer to FIG. 4, a cross-sectional view of a test table with dry environment according to the third embodiment of the present invention. The difference between the third embodiment and the first embodiment is that according to the third embodiment of the present invention, the test table 1 further comprises a housing 14 and a dry air pipe 15. The housing 14 covers an upper space of the test area 111. The dry air pipe 15 connects the dry air generator 13. The dry air generator 13 is disposed inside the housing 14 to generate a dry environment in the upper space of the test area 111 to prevent dew condensation.

In conclusion, the test table according to embodiments of the present invention comprises the flow guide mechanism to guide a dry air to the test area so as to create a dry environment covering the test table and the objects to be tested to prevent dew condensation or icing; therefore, the reliability of the electrical property test is improved.

While the present invention has been particularly shown and described with reference to a preferred embodiment, it will be understood by those skilled in the art that various changes in form and detail may be without departing from the spirit and scope of the present invention.

What is claimed is:

1. A test table with dry environment, the test table comprising:
a chuck base having a test area;
a flow guide mechanism disposed around the chuck base; and
a dry air generator connected to the flow guide mechanism for generating a dry air;
wherein the flow guide mechanism guides the dry air to flow toward the test area so as to prevent the dry environment from dew condensation.

2. The test table according to claim 1, wherein the flow guide mechanism comprises a guiding part for guiding the dry air to flow toward the test area when the dry air flows to the guiding part guiding part;

3. The test table according to claim 2, wherein the flow guide mechanism further comprises a plurality of outlets for the dry air flowing from the outlets to the guiding part.

4. The test table according to claim 3, wherein the flow guide mechanism further comprises an inlet connected to the dry air generator; the dry air entering the flow guide mechanism from the inlet and flowing to the outlets.

5. The test table according to claim 2, wherein the guiding part comprises a guiding angle for increasing a flow uniformity of the dry air flowing toward the test area.

6. The test table according to claim 1, the test table testing a wafer of LED chips.

7. The test table according to claim 1, further comprising:
a housing for covering an upper space of the test area; and
a dry air pipe connected to the dry air generator, the dry air generator disposed inside the housing for to generate the dry environment in the upper space of the test area to prevent the dew condensation.

8. The test table according to claim 1, wherein the dry air generator comprises an air filter.

9. The test table according to claim 1, wherein the chuck base has a function of temperature controlling to control the temperature of the test area.
